(19) United States
(12) Patent Application Publication
(10) Pub. No.: US 2014/0078708 A1
(43) Pub. Date: Mar. 20, 2014

(54) MOBILE TERMINAL

(71) Applicant: LG ELECTRONICS INC., Seoul (KR)

(72) Inventors: Insu SONG, Seoul (KR); Youngmin LEE, Seoul (KR); Hyosung PARK, Seoul (KR); Choonghwan SHIN, Seoul (KR); Jeongwook LEE, Seoul (KR); Byunghwa LEE, Seoul (KR)

(73) Assignee: LG ELECTRONICS INC., Seoul (KR)

(21) Appl. No.: 14/028,108

(22) Filed: Sep. 16, 2013

(30) Foreign Application Priority Data
Sep. 17, 2012 (KR) 10-2012-0102947

(51) Int. Cl. H05K 5/02

(52) U.S. Cl. CPC H05K 5/0217
USPC 361/809

(57) ABSTRACT

A mobile terminal including a camera module mounted in a terminal body and configured to capture an image; a frame mounted onto the terminal body to cover at least part of the camera module, the frame having a locking hole; and a cover coupled to the terminal body to cover the frame. Further, the cover includes a locking hook locked in the locking hole to fix a position of the frame when the cover is coupled to the terminal body.

### CROSS-REFERENCE TO RELATED APPLICATION

Pursuant to 35 U.S.C. §119(a), this application claims the benefit of earlier filing date and right of priority to Korean Application No. 10-2012-0102947, filed on Sep. 17, 2012, the contents of which is incorporated by reference herein in its entirety.

### BACKGROUND OF THE INVENTION

1. Field of the Invention

The present invention relates to a mobile terminal having a camera module.

2. Background of the Invention

Mobile terminals are electronic devices which are portable and have at least one of voice and telephone call functions, information input and/or output functions, a data storage function and the like. As it becomes multifunctional, the mobile terminal can capture still images or moving images, play music or video files, play games, receive broadcast and the like, so as to be implemented as an integrated multimedia player.

Many efforts are undergoing to support and enhance various functions as such multimedia player in view of hardware or software improvements. The attempts corresponding to the hardware improvement include structural changes and improvements for maintaining a firmly coupled state of an electronic device, preventing permeation of foreign materials and the like.

As one example, a camera module may be mounted on an internal structure, and a cover may be coupled to a terminal body to shield the camera module. When an impact is applied to the mobile terminal, the camera module may be separated from the internal structure. Movement of the camera module caused by the separation tends to generate cracks on a circuit pattern of a flexible printed circuit board connected to the camera module.

Also, when the cover is mounted to the terminal body to shield the camera module, pressure may not be applied directly onto the camera module, which causes the camera module to become loose. This results in permeation of foreign materials into the camera module.

### SUMMARY OF THE INVENTION

Therefore, an aspect of the detailed description is to provide a mobile terminal having a structure for maintaining a fixed state of a camera module onto a preset position and preventing foreign materials from permeating into the camera module.

To achieve these and other advantages and in accordance with the purpose of this specification, as embodied and broadly described herein, there is provided a mobile terminal including a camera module mounted in a terminal body to capture an image, a frame mounted onto the terminal body to cover at least part of the camera module, the frame having a locking hole, and a cover coupled to the terminal body to cover the frame, wherein the cover may include a locking hook locked in the locking hole to fix a position of the frame when the cover is coupled to the terminal body.

In accordance with one embodiment, the mobile terminal may further include a supporting member coupled to a first case defining an appearance of the terminal body, the frame being mounted onto the supporting member, and a printed circuit board disposed to cover the supporting member and having a hole for insertion of the camera module therethrough, the hole corresponding to the frame.

The mobile terminal may further include a first flexible printed circuit board connected to one side of the camera module to electrically connect the camera module to the printed circuit board, and an opening may be formed on the frame corresponding to the one side, to allow the first flexible printed circuit board to be inserted therethrough.

Here, the frame may include a locking jaw protruding to cover a part of the opening so as to prevent the camera module from being separated through the one side.

Also, the locking hole may be formed on each of surfaces, facing each other at both sides of the opening, for supporting the both sides of the camera module, so as to prevent breaking of wire of the first flexible printed circuit board due to lateral movement of the camera module.

The frame and the supporting member may be formed of a metal. In addition, the frame may include an extending portion protruding therefrom, and the printed circuit board may include an elastic contact pin elastically contactable with the extending portion to extend a ground.

The mobile terminal may further include a display disposed on a rear surface of the supporting member to output visual information and electrically connected to the printed circuit board via a second flexible printed circuit board, and a fixing portion extending from the frame and covering at least part of the second flexible printed circuit board to prevent separation of the second flexible printed circuit board.

In accordance with another embodiment of the present disclosure, the cover may include a receiving portion recessed to receive therein at least part of the camera module and having a transparent area corresponding to a lens of the camera module. Also, a sealing pad may be attached onto the receiving portion to wrap up the lens. The sealing pad may be pressed by the camera module and the cover when the locking hook is locked in the locking hole.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the detailed description.

### BRIEF DESCRIPTION OF THE DRAWINGS

The accompanying drawings, which are included to provide a further understanding of the invention and are incorporated in and constitute a part of this specification, illustrate embodiments and together with the description serve to explain the principles of the invention.

In the drawings:

FIG. 1 is a front perspective view of a mobile terminal in accordance with one embodiment of the present disclosure;

FIG. 2 is a rear perspective view of the mobile terminal shown in FIG. 1;

FIG. 3 is a disassembled perspective view of the mobile terminal of FIG. 1;

FIG. 4 is a sectional view taken along the line IV-IV of FIG. 2;

FIG. 5 is a disassembled perspective view showing a coupling concept between a cover and a frame shown in FIG. 3;

FIG. 6 is a conceptual view showing a ground extending structure of a printed circuit board connected to the frame shown in FIG. 3; and

FIG. 7 is a conceptual view showing a fixed structure of a second flexible printed circuit board using the frame of FIG. 3.

### DETAILED DESCRIPTION OF THE INVENTION

Description will now be given in detail of a mobile terminal and a method for fabricating an image module provided in the mobile terminal according to the embodiments, with reference to the accompanying drawings.

For the sake of brief description with reference to the drawings, the same or equivalent components will be provided with the same reference numbers, and description thereof will not be repeated. The expression in the singular form in this specification will cover the expression in the plural form unless otherwise indicated obviously from the context. Hereinafter, suffixes “module” and “unit or portion” for components used herein in description are merely provided only for facilitation of preparing this specification, and thus they are not granted a specific meaning or function.

Mobile terminals described in this specification may include cellular phones, smart phones, laptop computers, digital broadcasting terminals, personal digital assistants (PDAs), portable multimedia players (PMPs), E-books, navigators, and the like. However, the configuration according to the embodiments of this specification can be applied to stationary terminals such as digital TV, desktop computers and the like excluding a case of being applicable only to the mobile terminals.

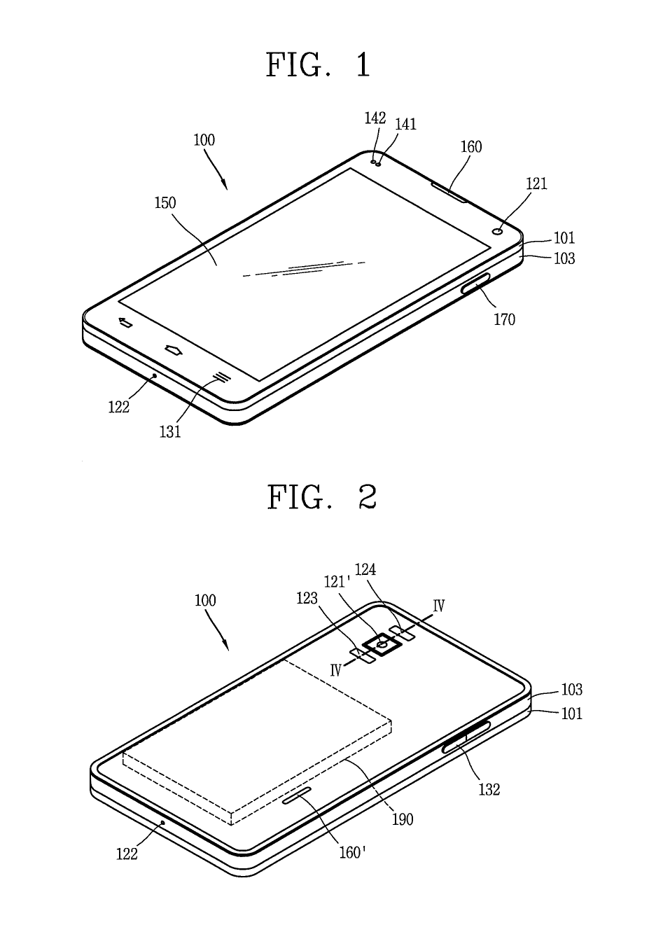

FIG. 1 is a front perspective view of a mobile terminal 100 in accordance with one embodiment. The mobile terminal 100 shown in FIG. 1 has a bar type terminal body. However, this detailed description may be applicable, but not limited to, a watch type, a clip type, a glass type, or a various structures, such as a slide type, a folder type, a swing type, a swivel type and the like, having two or more bodies coupled to be relatively movable with each other.

The terminal body may include a case (or referred to as casing, housing, cover, etc.) defining an appearance of the mobile terminal 100. In this embodiment, a main body is divided into a front case 101 and a rear case 103. Various electronic components are mounted in a space formed between the front case 101 and the rear case 102. A cover may be coupled to the front or rear case 101 or 103 to define a rear appearance of the mobile terminal 100. Such cases may be injected using a synthetic resin or be formed of a metal, such as stainless steel (STS), titanium (Ti), aluminum (Al) or the like.

The front surface of the terminal body is shown having a display unit 150, a proximity sensor 141, a light sensor 142, a first audio output module 160, a first camera module 121, a first manipulation unit 131 and the like, and a side surface thereof is shown having a microphone 122, an interface unit 170, a second manipulation unit 132 (see FIG. 2) and the like.

The display unit 150 outputs information processed in the mobile terminal 100. The display unit 150 may be implemented to display (output) visual information using, for example, at least one of a Liquid Crystal Display (LCD), a Thin Film Transistor-Liquid Crystal Display (TFT-LCD), an Organic Light-Emitting Diode (OLED), a flexible display, a three-dimensional (3D) display, an e-ink display or the like.

The display unit 150 may include a touch sensing unit for receiving a control command input in a touch manner. When a portion on the display unit 150 is touched, the touch sensing unit may sense the touch input and a content corresponding to the touched portion may be input. The contents input in the touch manner may include text or numerals or menu items which are instructed or selected in various modes.

Touch sensing unit may be transparent such that visual information output on the display unit 150 can be viewed, and have a structure for enhancing visibility of a touch screen at a bright place. In FIG. 1, the display unit 150 may occupy most of the front surface of the front case 101.

The proximity sensor 141, the light sensor 142, the first audio output module 160 and the first camera module 121 may be disposed at a region adjacent to one of both end portions of the display unit 150, and the first manipulation unit 131 and the microphone 122 may be disposed at a region adjacent to another end. A second manipulation unit 132, an interface unit 170 and the like may be disposed at a side surface of the terminal body.

The proximity sensor 141 may detect whether or not an object exists within a predetermined detection area, and be used to control other components including the display unit 150. As one example, the proximity sensor 141 may be disposed adjacent to the display unit 150 to control the display unit 150 to be deactivated when a user puts the terminal body onto his face to place or receive a call.

The light sensor 142 may sense brightness of ambient light of the terminal body. The mobile terminal 100 may automatically adjust lighting of the display unit 150 according to an amount of ambient light using the light sensor 142.

The first audio output module 160 may be implemented as a receiver to transfer a call sound to a user's ear, or a loud speaker for outputting various alarm sounds or multimedia reproduction sounds.

Sounds generated from the first audio output module 160 may be emitted through an assembly gap between structures. Here, a separately formed hole for outputting sounds may not be viewed or be hidden from the outside, thereby more simplifying the appearance of the terminal 100.

The first camera module 121 may receive and process image frames of still pictures or video obtained by image sensors in a video call mode or a capturing mode. The processed image frames may be displayed on a display unit 150.

A user input unit may be manipulated to allow inputting of commands for controlling operations of the mobile terminal 100, and include first and second manipulation units 131 and 132. The first and second manipulation units 131 and 132 may be referred to as a manipulating portion. Such manipulating portion can employ any tactile manner that a user can touch, push, scroll or the like for manipulation.

The drawings illustrate the first manipulation unit 131 as a touch key, but the present disclosure is not limited to the type. For example, the first manipulation unit 131 may be implemented as a mechanical key or a combination of a touch key and a push key.

Contents input by the first and second manipulation units 131 and 132 may be set variously. For example, the first manipulation unit 131 may be configured to input commands such as menu, home, cancel, search or the like, and the second manipulation unit 132 may be configured to input commands, such as a volume adjustment of sounds output from the first audio output module 160, conversion of the display unit 150 into a touch recognition mode, or the like.

The microphone 122 can receive user's voice, other sounds and the like. The microphone 122 may be disposed in various places to receive stereo sound.

The interface unit 170 serves as a path for data exchange between the mobile terminal 100 and external devices. For example, the interface unit 170 may be at least one of wired/wireless earphone ports, ports for short-range communication (e.g., IrDA, Bluetooth, WLAN, etc.), power supply terminals for power supply to the mobile terminal and the like. The interface unit 170 may be a card socket for coupling to external cards, such as a Subscriber Identity Module (SIM), a User Identity Module (UIM), a memory card for storage of information and the like.

Next, FIG. 2 is a rear perspective view of the mobile terminal 100 shown in FIG. 1. Referring to FIG. 2, the rear surface of the terminal body is further shown having a second camera module 121′. The second camera module 121′ faces a direction which is substantially opposite to a direction faced by the first camera module 121 (see FIG. 1). Also, the second camera module 121′ may be a camera having different pixels from those of the first camera module 121.

For example, the first camera module 121 may operate with relatively lower pixels (lower resolution). Thus, the first camera module 121 may be useful when a user can capture his face and send it to another party during a video call or the like. On the other hand, the second camera module 121′ may operate with relatively higher pixels (higher resolution) such that it can be useful for a user to obtain higher quality pictures for later use.

A flash 123 and a mirror 124 may be disposed adjacent to the second camera 121′. The flash 123 operates in conjunction with the second camera module 121′ when taking a picture using the second camera module 121′. The mirror 124 can cooperate with the second camera module 121′ to allow a user to photograph himself in a self-portrait mode.

A second audio output module 160′ may further be disposed on the rear surface of the terminal body. The second audio output module 160′ may cooperate with the first audio output unit 160 (see FIG. 1) to provide stereo output in a phone-call mode, and be used to implement a speakerphone mode during a call connection.

A broadcast signal receiving antenna may further be disposed at the side surface of the terminal body, in addition to an antenna for call connection. The antenna forming a part of the broadcast receiving module may be retractably into the terminal body.

The terminal body is shown having a power supply unit 190 for supplying power to the mobile terminal 100. The power supply unit 190 may be implemented as a battery 191 for converting chemical energy into electrical energy, and the battery may be mounted inside the terminal body or detachably coupled to the terminal body.

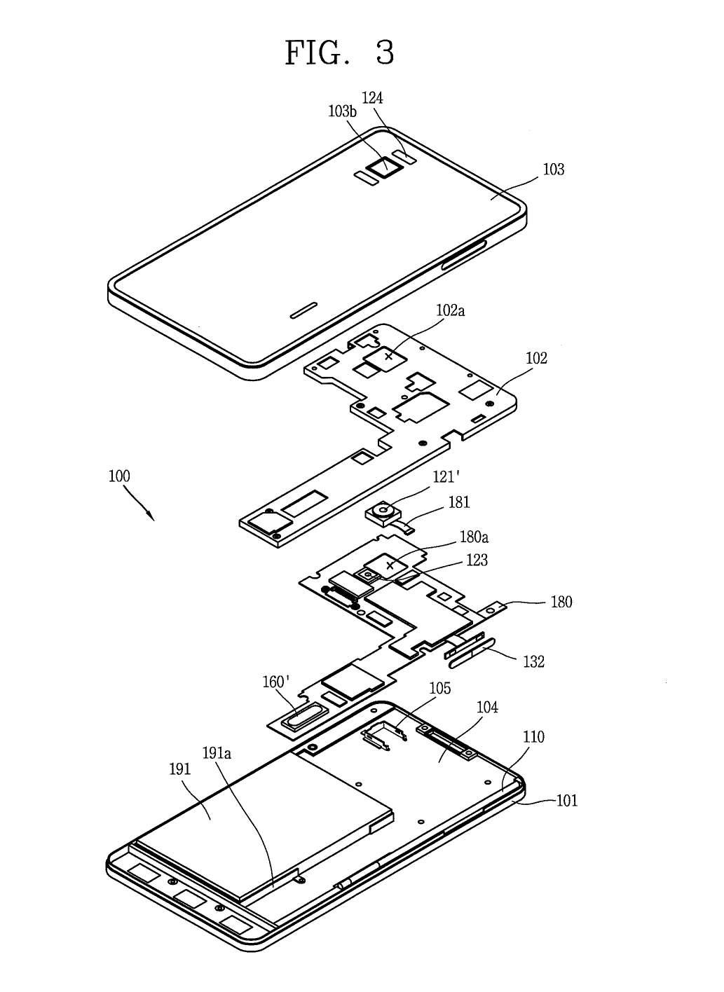

Next, FIG. 3 is a disassembled perspective view of the mobile terminal 100 shown in FIG. 2. As shown in FIG. 3, the front case 101 includes a cavity. A supporting member 104 is also coupled to the front case 101 to cover the cavity, thereby forming a mounting or arrangement space for various electronic devices or internal structures. The supporting member 104 may be made of a metal sheet (for example, stainless steel) having a thin thickness (for example, about 0.2 mm) and high rigidity.

A display is disposed on a front surface of the supporting member 104 to output visual information onto the front surface of the terminal body. Referring to FIG. 3, a printed circuit board 180 is located on a rear surface of the supporting member 104.

The printed circuit board 180 may be implemented as one example of a controller for operating various functions of the mobile terminal 100. The printed circuit board 180 may have a proper shape according to internal structures. In the drawing, the printed circuit board 180 has a hole 180a corresponding to a frame 105 such that the second camera module 121′ can be inserted through the printed circuit board 180.

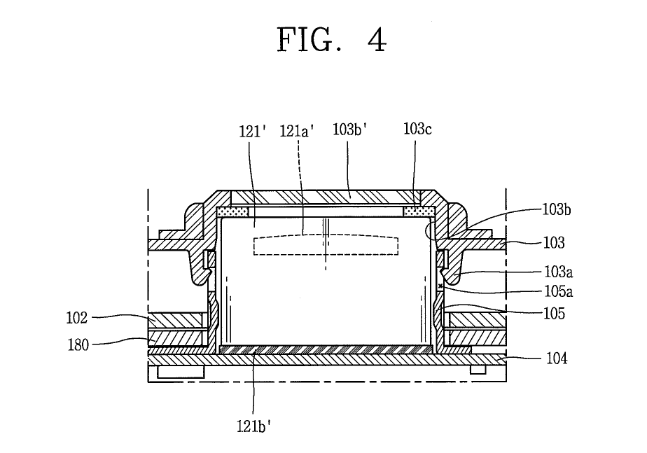

The aforementioned second camera module 121′ is mounted onto the supporting member 104 using SMT, an adhesive tape 121b′ (FIG. 4) or the like. Here, the second camera module 121′ may be located at a position spaced inwardly from a sidewall of the front case 101 by a predetermined gap. The second camera module 121′ may be inserted through the hole 180a of the printed circuit board 180 to protrude onto the printed circuit board 180. Also, the second camera module 121′ is electrically connected to the printed circuit board 180 via a first flexible printed circuit board 181.

The rear case 103 is coupled to the front case 101 to cover the printed circuit board 180. The rear case 103 protects circuit elements by covering the printed circuit board 180. The rear case 103 includes a through hole 102a such that the second camera module 121′ can be inserted therethrough. As shown, the rear case 103 is not exposed to the appearance of the terminal body.

The supporting member 104 includes a battery receiving portion 191a which forms a space for receiving the battery 191 therein. The battery receiving portion 191a may be formed by bending a metal sheet (for example, stainless steel which is about 0.02 mm thick) into a shape of a sidewall to cover a side surface of the battery 191. The battery receiving portion 191a may be firmly fixed onto the supporting member 104 in a welding manner. Further, the battery 191 may be received in the battery receiving portion 191a to supply power to the terminal main body.

The cover 103 can be coupled to the front case 101 to define a rear appearance of the terminal body. In particular, the cover 103 may be detachably coupled to the front case 101 using a locking structure (stopping structure) with hooks or firmly coupled to the front case 101 using coupling members or the like.

Hereinafter, description will be given of a structure that the second camera module 121′ can remain in a firmly coupled state in spite of impact applied thereto and permeation of foreign materials into the second camera module 121′ can be prevented.

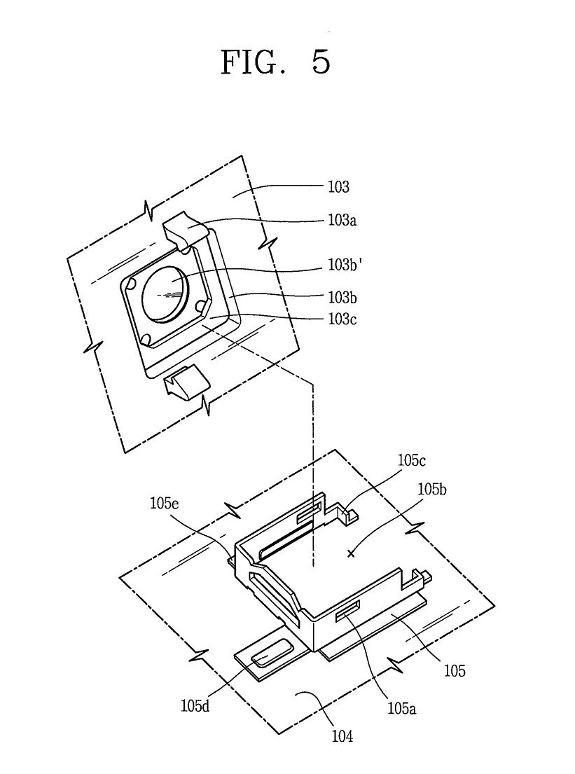

FIG. 4 is a sectional view taken along the line IV-IV of FIG. 2, and FIG. 5 is a disassembled perspective view showing a coupling concept between the cover 103 and the frame 105 shown in FIG. 3. As shown in FIGS. 4 and 5 together with FIG. 3, the frame 105 is mounted onto the supporting member 104 to cover at least part of the second camera module 121′.

Further, the frame 105 supports the second camera module 121′ to be fixed onto a preset position. The frame 105 may be made of the metal sheet (for example, stainless steel which is about 0.02 mm thick) as the same as the supporting member 104. Also, the frame 105 may be bent into a shape of sidewall to cover side surfaces of the second camera module 121′. The frame 105 may be firmly fixed onto the supporting member 104 in a welding manner.

The second camera module 121′ is mounted in the frame 105. A first flexible printed circuit board 181 may be connected to one side of the second camera module 121′ such that the second camera module 121′ and the printed circuit board 180 can be electrically connected to each other. As shown, an opening 105b through which the first flexible printed circuit board 181 is inserted is formed on a portion of the frame 105 corresponding to the one side of the second camera module 121′.

That is, the frame 105 is formed to cover the other side surfaces of the second camera module 121′ except for the one side of the second camera module 121′. Here, locking jaws 105c protrude from both sides of the opening 105b to partially block the opening 105b such that the second camera module 121′ can be prevented from being separated through the one side.

A locking hook 103a is also formed on the frame 105 such that a locking hook 103a of the cover 103 to be explained later can be locked (stopped) therein. The embodiment illustrates that the frame 105 is made of the metal sheet and the portion at which the locking hook 103a is stopped is bored. However, the present invention is not limited to the structure. For example, the locking hole 105a may be formed in form of a locking recess.

To fix the frame 105 of the cover 103 which will be explained in more detail later, the locking hole 105a may be preferably formed on at least two sidewalls which cover the side surfaces of the second camera module 121′. The locking holes 105a may be formed on surfaces which face each other at both sides of the opening 105b. Accordingly, the cover 103 prevents the second camera module 121′ from being moved in a lateral direction which intersects with an extending direction of the first flexible printed circuit board 181. Therefore, both sides of the second camera module 121′ are supported so as to prevent breaking of wire of the first flexible printed circuit board 181, which may be caused due to the lateral movement of the second camera module 121′.

In addition, the locking hole 103a protrudes from an inner surface of the cover 103 to be locked in the locking hole 105a. When the cover 103 is coupled to the front case 101, the locking hook 103a is locked in the locking hole 104a. This allows the cover 103 to be coupled even to the frame 105. Accordingly, the frame 105 can be coupled to the cover 103 by the locking structure in the mounted state onto the supporting member 104. Also, the locking structure applies a more direct coupling force to the second camera module 121′.

Even if the frame 105 is separated from the supporting member 104 due to impact, the frame 105 may still be in the coupled state to the cover 103 by virtue of the locking structure, so as to be kept located on the preset position. This may result in preventing generation of cracks on a circuit pattern of the first flexible printed circuit board 181 connected to the second camera module 121′.

In addition, the cover 103 includes a receiving portion 103b, which is recessed to receive therein at least part of the second camera module 121′. The receiving portion 103b is further disposed to cover the second camera module 121′. A portion of the receiving portion 103b which corresponds to a lens 121a′ of the second camera module 121′ is also implemented as a transparent area 103b′.

A sealing pad 103c for wrapping up the lens 121a′ is also attached onto the receiving portion 103b. The sealing pad 103c may be made of an elastic material. A thickness of the sealing pad 103c may be thicker than a gap between the second camera module 121′ and the cover 103. When the cover 103 is coupled to the frame 105 as the locking hook 103a is locked in the locking hole 105a, the sealing pad 103c is pressed by the second camera module 121′ and the cover 103.

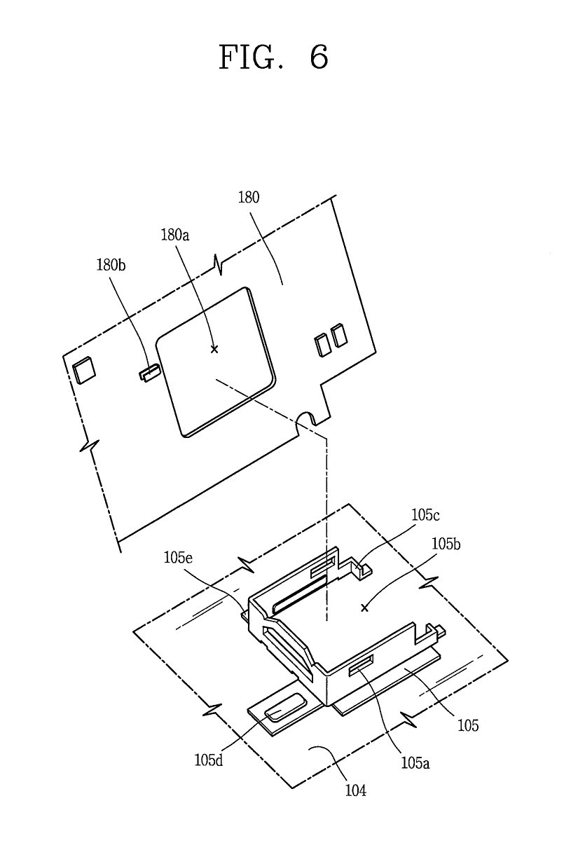

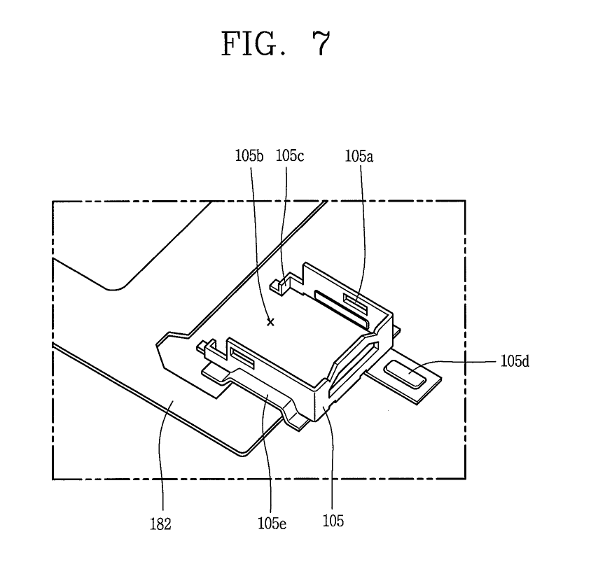

With the structure, the cover 103 is fixed onto the frame 105 as well as the terminal body, thereby applying pressure more directly onto the sealing pad 103c. This prevents foreign materials from permeating into the second camera module 121′, and also prevents the corresponding portion of the cover 103 from being protruded or deformed due to a restoring force of the sealing pad 103c. An extending portion 105d and a fixing portion 105e are described in FIGS. 6 and 7.

Next, FIG. 6 is a conceptual view showing a ground extending structure of the printed circuit board 180 connected to the frame 105 shown in FIG. 3. As shown in FIG. 6, an extending portion 105d protrudes from the frame 105. The extending portion 105d is formed in a shape that a part of the frame 105 is bent to cover the supporting member 104. The extending portion 105d may also be firmly coupled onto the supporting member 104 in a welding manner.

In addition, an elastic contact pin 180b is placed on a surface of the printed circuit board 180 which faces the supporting member 104. The elastic contact pin 180b, for example, may be Pogo pin, C-Clip and the like. Upon mounting the printed circuit board 180, the elastic contact pin 180b elastically contacts the extending portion 105d so as to extend a ground. Here, the extending portion 105d is in the coupled state to the supporting member 104. Therefore, the supporting member 104 can function as the ground.

FIG. 7 is a conceptual view showing a fixed structure of the second flexible printed circuit board 182 using the frame 105 of FIG. 3. As shown in FIG. 7, a display is electrically connected to the printed circuit board 180 via a second flexible printed circuit board 182. FIG. 7 illustrates that the second flexible printed circuit board 182 extends from one surface to another surface of the supporting member 104 in a curved state.

Referring to FIG. 7, the second flexible printed circuit board 182 is formed long in at least one direction. When the second flexible printed circuit board 182 becomes long, it may cause difficulty in arranging wires during processes. To solve the difficulty, in some instances, the second flexible printed circuit board 182 may be fixed using a tape.

The present invention may be implemented such that the frame 105 can secure the second flexible printed circuit board 182. In more detail, a fixing portion 105e may be formed on one side of the frame 105 to cover at least part of the second flexible printed circuit board 182. FIG. 7 illustrates a structure that the fixed portion 105e is formed in a shape like an alphabet “U” and receives the second flexible printed circuit board 182 therein to prevent separation of the second flexible printed circuit board 182.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the embodiments described herein may be combined in various ways to obtain additional and/or alternative embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A mobile terminal comprising:
a camera module mounted in a terminal body and configured to capture an image;
a frame mounted onto the terminal body to cover at least part of the camera module, the frame having a locking hole; and
a cover coupled to the terminal body to cover the frame,
wherein the cover includes a locking hook locked in the locking hole to fix a position of the frame when the cover is coupled to the terminal body.

2. The mobile terminal of claim 1, further comprising:
a supporting member coupled to a first case defining an appearance of the terminal body, the frame being mounted onto the supporting member; and
a printed circuit board disposed to cover the supporting member and having a hole for insertion of the camera module therethrough, the hole corresponding to the frame.

3. The mobile terminal of claim 2, further comprising:
a first flexible printed circuit board connected to one side of the camera module to electrically connect the camera module to the printed circuit board; and
an opening formed on the frame corresponding to the one side of the camera module, the opening allowing the first flexible printed circuit board to be inserted therethrough.

4. The mobile terminal of claim 3, wherein the frame includes a locking jaw protruding to cover a part of the opening so as to prevent the camera module from being separated through the one side of the camera module.

5. The mobile terminal of claim 3, wherein the locking hole is formed on each of surfaces, facing each other at both sides of the opening, for supporting the both sides of the camera module, so as to prevent breaking of wire of the first flexible printed circuit board due to lateral movement of the camera module.

6. The mobile terminal of claim 2, wherein the frame and the supporting member include a metal.

7. The mobile terminal of claim 6, wherein the frame includes an extending portion protruding therefrom, and
wherein the printed circuit board includes an elastic contact pin elastically contactable with the extending portion to extend a ground.

8. The mobile terminal of claim 3, further comprising:
a display disposed on a rear surface of the supporting member and configured to display visual information, the display being electrically connected to the printed circuit board via a second flexible printed circuit board; and
a fixing portion extending from the frame, the fixing portion covering at least part of the second flexible printed circuit board to prevent separation of the second flexible printed circuit board.

9. The mobile terminal of claim 1, wherein the cover includes a receiving portion recessed to receive therein at least part of the camera module, the receiving portion having a transparent area corresponding to a lens of the camera module.

10. The mobile terminal of claim 9, further comprising:
a sealing pad attached onto the receiving portion to wrap up the lens, the sealing pad being pressed by the camera module and the cover when the locking hook is locked in the locking hole.

11. A mobile terminal comprising:
a wireless communication unit configured to wirelessly communicate with at least one other terminal;
a display configured to display information;
a camera module mounted in a terminal body and configured to capture an image;
a three-sided frame mounted onto the terminal body to cover three sides of the camera module, the frame having a locking hole; and
a cover integral with the terminal body and including a locking hook configured to lock into the locking hole to secure the camera module within the frame and cover.

12. The mobile terminal of claim 11, further comprising:
a supporting member coupled to a first case defining an appearance of the terminal body, the frame being mounted onto the supporting member; and
a printed circuit board disposed to cover the supporting member and having a hole for insertion of the camera module therethrough, the hole corresponding to the frame.

13. The mobile terminal of claim 12, further comprising:
a first flexible printed circuit board connected to one side of the camera module to electrically connect the camera module to the printed circuit board; and
an opening formed on the frame corresponding to the one side of the camera module, the opening allowing the first flexible printed circuit board to be inserted therethrough.

14. The mobile terminal of claim 13, wherein the frame includes a locking jaw protruding to cover a part of the opening so as to prevent the camera module from being separated through the one side of the camera module.

15. The mobile terminal of claim 13, wherein the locking hole is formed on each of surfaces, facing each other at both sides of the opening, for supporting the both sides of the camera module, so as to prevent breaking of wire of the first flexible printed circuit board due to lateral movement of the camera module.

16. The mobile terminal of claim 12, wherein the frame and the supporting member include a metal.

17. The mobile terminal of claim 16, wherein the frame includes an extending portion protruding therefrom, and
wherein the printed circuit board includes an elastic contact pin elastically contactable with the extending portion to extend a ground.

18. The mobile terminal of claim 13, wherein the display is disposed on a rear surface of the supporting member, the display being electrically connected to the printed circuit board via a second flexible printed circuit board; and
a fixing portion extending from the frame, the fixing portion covering at least part of the second flexible printed circuit board to prevent separation of the second flexible printed circuit board.

19. The mobile terminal of claim 11, wherein the cover includes a receiving portion recessed to receive therein at least part of the camera module, the receiving portion having a transparent area corresponding to a lens of the camera module.

20. The mobile terminal of claim 19, further comprising:
a sealing pad attached onto the receiving portion to wrap up the lens, the sealing pad being pressed by the camera module and the cover when the locking hook is locked in the locking hole.
